(19) United States
(12) Patent Application Publication
(10) Pub. No.: US 2014/0048199 A1
(43) Pub. Date: Feb. 20, 2014

(54) ADHESIVE TAPE AND METHOD FOR PRODUCING SUBSTRATE USING THE SAME

(71) Applicant: SAMSUNG ELECTRO-MECHANICS CO., LTD., Suwon (KR)

(72) Inventors: Dae Jun Kim, Suwon (KR); Jong Sik Kim, Suwon (KR)

(73) Assignee: Samsung Electro-Mechanics Co., Ltd., Suwon (KR)

(21) Appl. No.: 13/655,057

(22) Filed: Oct. 18, 2012

(30) Foreign Application Priority Data
Aug. 17, 2012 (KR) 10-2012-0090323

(51) Int. Cl. C09J 7/02; B32B 7/02; B32B 33/00; H05K 13/00; B32B 7/12

(52) U.S. Cl. 156/247; 428/354; 428/41.8; 428/213

(57) ABSTRACT

There are provided an adhesive tape and a method for producing a substrate using the same. The adhesive tape including: a reinforcement layer supporting the adhesive tape; a buffer layer formed on one surface of the reinforcement layer and performing a buffering operation; and an adhesive layer formed on one surface of the buffer layer.

### CROSS-REFERENCE TO RELATED APPLICATIONS

This application claims the priority of Korean Patent Application No. 10-2012-0090323 filed on Aug. 17, 2012, in the Korean Intellectual Property Office, the disclosure of which is incorporated herein by reference.

### BACKGROUND OF THE INVENTION

1. Field of the Invention

The present invention relates to an adhesive tape and a method for producing a substrate using the same.

2. Description of the Related Art

Adhesive tape has characteristics in which it may be adhered to an object by simple contact therewith and then easily separated therefrom. Due to the above-mentioned characteristics, adhesive tape has been used in various applications for producing electrical and electronic components.

Among others, an adhesive tape for temporarily fixing components mounted on a substrate should maintain a high degree of adhesive force while being fixed and be easily removed even by weak force while being separated. That is, adhesive tape residue should not remain on a substrate or components and should be able to be easily removed therefrom.

The occurrence of residue from adhesive tape for temporarily fixing components is mainly associated with pressure, temperature, and a surface state of the substrate during a process.

Particularly, in the case in which vacuum and thermal-pressure processes are performed on a substrate having circuit patterns formed on a surface thereof or having a prominence-depression part formed therein in order to improve adhesion with a stacked material, local pressing on the adhesive tape and deformation of a tape base substrate may occur.

In this condition, excessive adhesive tape residue may remain when the adhesive tape is removed.

As a method for reducing the residue at the time of removing adhesive tape, there are provided a method for increasing cohesive force of an adhesive itself, a method for decreasing the adhesive force, a method for increasing adhesion between an adhesive and a base substrate, and the like.

However, the occurrence of adhesive tape residue may not be significantly decreased through only using the method described above.

Meanwhile, in the case in which residue remains on the prominence-depression part in the process of producing the substrate, an additional process for removing the residue is required. In addition, a substrate discard ratio may also increase.

Therefore, introducing an adhesive tape structure capable of suppressing the occurrence of adhesive tape residue is required.

### RELATED ART DOCUMENT

(Patent Document 1) Korean Patent Laid-Open Publication No. 2012-0029364
(Patent Document 2) Japanese Patent Laid-Open Publication No. 2004-0253612

### SUMMARY OF THE INVENTION

An aspect of the present invention provides an adhesive tape capable of suppressing the occurrence of residue therefrom.

According to an aspect of the present invention, there is provided an adhesive tape including: a reinforcement layer supporting the adhesive tape; a buffer layer formed on one surface of the reinforcement layer and performing a buffering operation; and an adhesive layer formed on one surface of the buffer layer.

The adhesive tape may further include a release film formed on one surface of the adhesive layer.

The adhesive tape may further include an adhering layer formed on at least one of an interface between the buffer layer and the adhesive layer and an interface between the buffer layer and the reinforcement layer.

The reinforcement layer may include at least one of a copper foil and an aluminum foil.

The reinforcement layer may include at least one of polyethylene terephtalate, polyimde, polyolefine, and polyethylene naphtalate.

The buffer layer may include at least one of polyethylene terephtalate, polyimde, polyolefine, and polyethylene naphtalate.

The adhesive layer may include at least one of acryl, silicone, and urethane.

The release film may include polyethylene terephtalate.

A thickness ratio of the buffer layer to the reinforcement layer may be 1:1 to 1:4.

According to another aspect of the present invention, there is provided a method for producing a substrate, the method including: preparing a core substrate having circuit patterns formed on both surfaces thereof and a cavity formed to penetrate through upper and lower portions thereof; laminating an adhesive tape on a lower surface of the core substrate so as to shield a lower portion of the cavity, the adhesive layer including a reinforcement layer, a buffer layer, and an adhesive layer; embedding an electronic component in the cavity; laminating a first insulator on an upper surface of the core substrate; removing the adhesive tape; and laminating a second insulator on the lower surface of the core substrate.

The method may further include forming an adhering layer on at least one of an interface between the buffer layer and the adhesive layer and an interface between the buffer layer and the reinforcement layer.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A through 1F are cross-sectional views showing a method for producing a substrate using an adhesive tape;

FIG. 2A is a cross-sectional view of the adhesive tape; and FIG. 2B is a cross-sectional view of the adhesive tape adhered to the substrate;

FIG. 3A is a cross-sectional view of an adhesive tape according to an embodiment of the present invention and FIG. 3B is a cross-sectional view of the adhesive tape according to the embodiment of the present invention adhered to a substrate;

FIGS. 4A through 4D are cross-sectional views of an adhesive tape according to another embodiment of the present invention; and

FIGS. 5A through 5D are cross-sectional views of an adhesive tape according to another embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

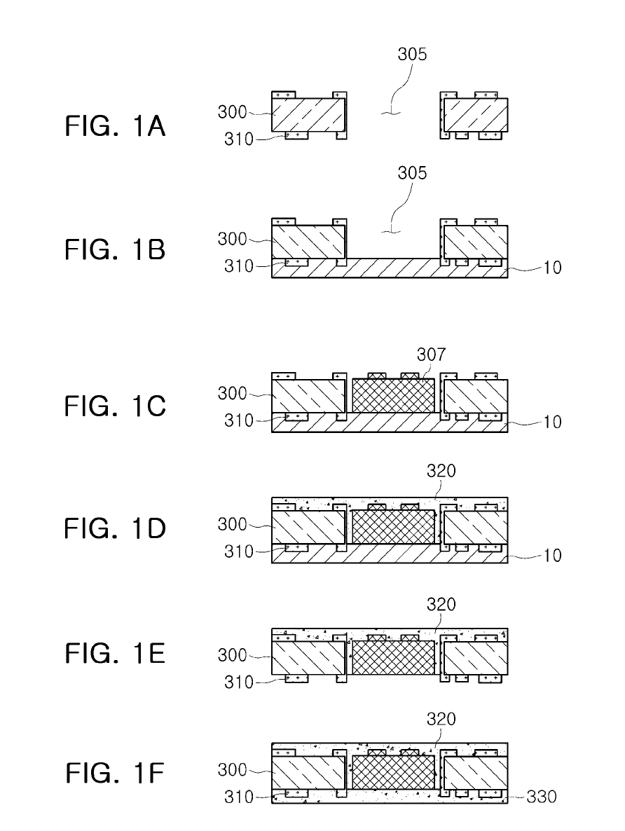

FIGS. 1A through 1F are views showing a method for producing a substrate using an adhesive tape.

The substrate may include a core substrate 300 forming a central layer, a chip 307 embedded in the substrate, and a first insulator 320 and a second insulator 330 covering both surfaces of the substrate.

In order to produce the substrate, the following processes are performed.

First, the core substrate 300 may be prepared as shown in FIGS. 1A through 1F.

The core substrate 300 may be provided with circuit patterns 310.

Further, the core substrate 300 may be provided with a cavity 305 penetrating from an upper portion of the core substrate to a lower portion thereof. That is, the core substrate 300 may be provided with the cavity 305 so that the chip 307 may be embedded therein. The chip 307 may be embedded in the cavity 305 by a subsequent process, wherein the cavity 305 may have a larger horizontal area than that of the chip 307 in order to form a space enough to embed the chip 307 therein.

After the core substrate 300 is prepared, an adhesive tape 10 may be laminated on a lower surface of the core substrate 300 to shield a lower portion of the cavity 305, as shown in FIG. 1B.

Next, the chip 307 may be adhered to the adhesive tape 10 to thereby be embedded in the cavity 305, as shown in FIG. 1C.

Next, the first insulator 320 may be laminated on an upper surface of the core substrate 300, as shown in FIG. 1D. The first insulator 320 may be in a semi-hardened state. When the first insulator 320 in the semi-hardened state is laminated, the first insulator 320 is introduced into the cavity 305.

As such, when the first insulator 320 is laminated, a gap between the chip 307 and the cavity 305 may be filled. Therefore, a separate process of stably fixing the chip 307, as an example, a process of filling the gap with a separate liquid-phase material and hardening the liquid-phase material, or the like, is not performed, such that the process may be simplified.

Next, the adhesive tape 10 may be removed as shown in FIG. 1E. In the process of removing the adhesive tape 10, residue may remain on a prominence-depression part formed by the core substrate 300 and the circuit pattern 310.

The residue caused due to the adhesive tape will be described below in detail.

Next, the second insulator 330 may be laminated on the lower surface of the core substrate 300, as shown in FIG. 1F. The second insulator 330 may be a semi-hardened state, similar to the first insulator 320.

As described above, the adhesive tape may be used in a process of producing the substrate.

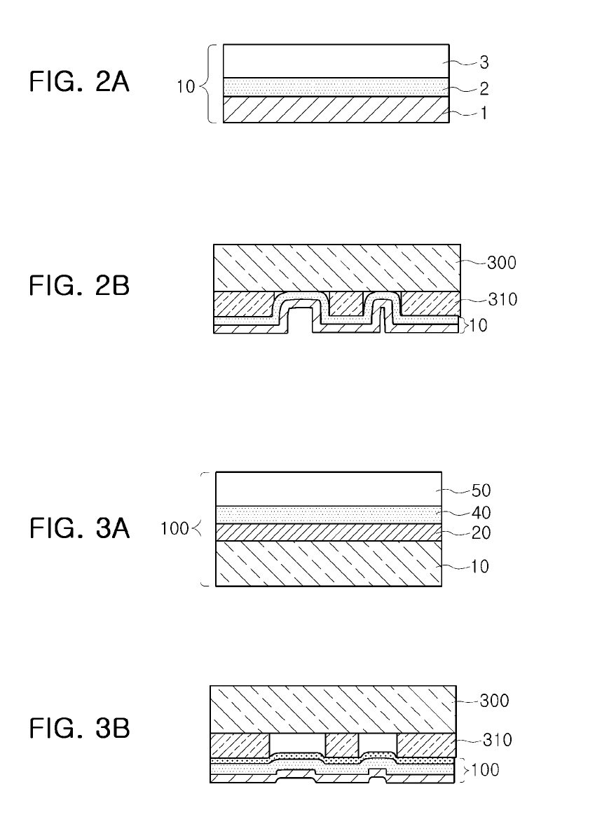

FIG. 2A is a cross-sectional view of the adhesive tape and FIG. 2B is a cross-sectional view of the adhesive tape adhered to the substrate.

Referring to FIG. 2A, the adhesive tape 10 may include a base substrate 1, an adhesive layer 2 formed on the base substrate 1, and a release film 3 formed on the adhesive layer 2.

As the base substrate 1, general plastic films, for example, polyethylene terephtalate (PET), or the like, may be used.

In addition, the adhesive layer 2 may be formed of adhesive resins having a degree of adhesive force capable of adhering the substrate and the adhesive tape to one another, for example, an acrylic resin, a silicone resin, and an epoxy resin.

The release film 3 may be used in order to maintain adhesion of the adhesive tape 10. For example, while storing the adhesive tape 10, the release film 3 may be attached to the adhesive tape 10. In addition, in the case in which the adhesive tape 10 needs to be used, the release film 3 may be removed.

In the case in which thermal-pressure is applied to the adhesive tape 10 in the state in which the adhesive tape 10 is adhered to the substrate having the prominence-depression part, the adhesive tape 10 may be deformed.

FIG. 2B shows the state in which the adhesive tape 10 is deformed due to thermal pressure applied thereto.

Local pressing may occur in a portion of the adhesive tape 10 adhered to an angled portion of the circuit pattern 310. That is, the portion of the adhesive tape 10 adhered to the angled portion may have large amount of pressure applied thereto.

Therefore, in the process of removing the adhesive tape 10, a large amount of residue may remain from the portion of the adhesive tape 10 adhered to the angled portion.

In addition, the residue may also remain on a concave portion formed by the substrate 300 and the circuit pattern 310.

In the case in which the residue remains on the concave portion, it may be very difficult to remove the residue therefrom.

FIG. 3A is a cross-sectional view of an adhesive tape according to an embodiment of the present invention and FIG. 3B is a cross-sectional view of the adhesive tape according to the embodiment of the present invention adhered to a substrate.

Referring to FIG. 3A, an adhesive tape 100 may include a reinforcement layer 10 supporting the adhesive tape, a buffer layer 20 formed on one surface of the reinforcement layer 10 and performing a buffering operation, an adhesive layer 40 formed on one surface of the buffer layer 20, and a release film 50 formed on one surface of the adhesive layer 40.

Here, the reinforcement layer 10 and the buffer layer 20 are defined as a base substrate.

The reinforcement layer 10 may serve to significantly decrease deformation of the adhesive tape 100 in a thermal-pressure process. For example, the reinforcement layer 10 may support the adhesive tape 100 in the thermal-pressure process to significantly decrease deformation of the adhesive tape 100.

The reinforcement layer may include a copper foil, an aluminum foil, and the like.

In addition, the reinforcement layer 10 may include polyethylene terephtalate, polyimide, polyolefine, polyethylene naphtalate, and the like.

The material for the reinforcement layer 10 may be appropriately selected according to process characteristics. A description thereof will be provided in detail below.

The buffer layer 20 may serve to absorb external force applied to the adhesive tape 100. For example, local pressing may occur in a portion of the adhesive tape 100 adhered to an angled portion of the circuit pattern 310. That is, the portion of the adhesive tape 100 adhered to the angled portion may have a large amount of pressure applied thereto.

In this case, the buffer layer 20 may serve to absorb the pressure to buffer the local pressing.

The buffer layer 20 may include polyethylene terephtalate (PET), polyimide (PI), polyolefine (PO), polyethylene naphtalate (PEN), and the like.

The material for the buffer layer 20 may be appropriately selected according to process characteristics. A description thereof will be provided in detail below.

The adhesive layer 40 may be formed of adhesive resins having adhesion capable of adhering the substrate and the base substrate, for example, an acrylic resin, a silicone resin, a urethane resin, and the like.

According to the embodiment of the present invention, the adhesive layer 40 may include acryl, silicone, urethane, and the like.

The release film 50 may be used in order to maintain adhesion of the adhesive tape 100. For example, while storing the adhesive tape 100, the release film 50 may be attached to the adhesive tape 100. In addition, in the case in which the adhesive tape 100 needs to be used, the release film 50 may be removed.

The release film may include polyethylene terephtalate.

In the case in which thermal-pressure is applied to the adhesive tape 10 in the state in which the adhesive tape 10 is adhered to the substrate having the prominence-depression part, the adhesive tape 100 may be deformed.

FIG. 3B shows the state in which the adhesive tape 100 is deformed due to the thermal pressure applied thereto.

The deformation toward the concave portion is less in the adhesive tape 100 according to the embodiment of the present invention as compared with the adhesive tape 10 shown in FIG. 2B. The reason therefor is that the reinforcement layer 10 supports the adhesive tape 100 to significantly decrease the deformation thereof.

In addition, the buffer layer 20 alleviates local pressing occurring in the case in which the adhesive tape 100 is adhered to the angled portion of the circuit pattern 310. Therefore, in the adhesive tape according to the embodiment of the present invention, damages due to local pressing may be alleviated.

In the adhesive tape 100 according to the embodiment of the present invention as described above, the deformation toward the concave portion is decreased, such that it is less likely that the residue will remain on the concave portion.

Further, in the adhesive tape 100 according to the embodiment of the present invention, the local pressing is alleviated, such that a majority of a residue remaining phenomenon at a point at which local pressing occurs may be suppressed.

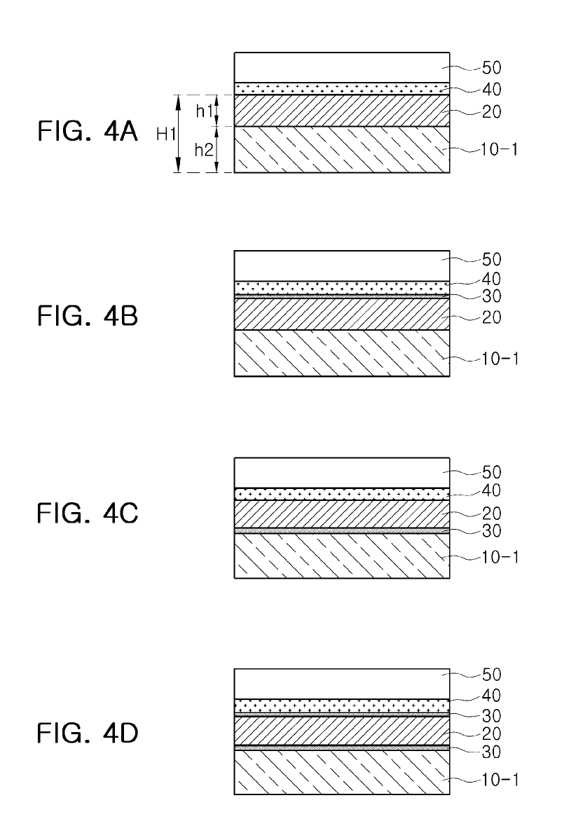

FIGS. 4A through 4D are cross-sectional views of an adhesive tape according to another embodiment of the present invention.

FIGS. 4A through 4D are views showing the adhesive tape in the case in which a reinforcement layer is formed of a metal foil.

As shown in FIG. 4A, the adhesive tape may include a metal foil reinforcement layer 10-1, a buffer layer 20 formed on one surface of the metal foil reinforcement layer 10-1 and performing a buffering operation, an adhesive layer 40 formed on one surface of the buffer layer 20, and a release film 50 formed on one surface of the adhesive layer 40.

According to the embodiment of the present invention, a thickness of a base substrate (H1) including the metal foil reinforcement layer 10-1 and the buffer layer 20 may be 30 μm or more.

In the case in which the thickness of the base substrate is 30 μm or less, reinforcement force may be significantly weakened.

Further, according to the embodiment of the present invention, a ratio (h1:h2) of a thickness (h2) of the metal foil reinforcement layer 10-1 to a thickness (h1) of the buffer layer 20 may be 1:1 to 1:4.

In the case in which the thickness (h1) of the buffer layer is thicker than the thickness (h2) of the reinforcement layer, an effect of the reinforcement layer may be significantly decreased.

In the case in which the thickness (h1) of the buffer layer is thinner than (for example, is 25% or less of) the thickness (h2) of the reinforcement layer, an effect of the buffer layer may be significantly decreased.

Referring to FIG. 4B, the adhesive tape may further include an adhering layer 30 disposed on an interface between the buffer layer 20 and the adhesive layer 40.

The adhering layer 30 may improve a degree of adhesion between the buffer layer 20 and the adhesive layer 40, respectively disposed on both surfaces thereof.

The adhering layer 30 may include acryl, silicone, urethane, and the like.

The material for the adhering layer 30 may be appropriately selected according to the materials configuring the buffer layer 20 and the reinforcement layer 10-1. A description thereof will be provided in detail below.

Referring to FIG. 4C, the adhesive tape may further include an adhering layer 30 disposed on an interface between the metal foil reinforcement layer 10-1 and the buffer layer 20.

The adhering layer 30 may improve a degree of adhesion between the metal foil reinforcement layer 10-1 and the buffer layer 20 respectively disposed on both surfaces thereof.

Referring to FIG. 4D, the adhesive tape may further include adhering layers 30 respectively disposed at the interface between the buffer layer 20 and the adhesive layer 40 and at the interface between the metal foil reinforcement layer 10-1 and the buffer layer 20.

The plurality of adhering layers 30 may improve a degree of adhesion between the metal foil reinforcement layer 10-1, the buffer layer 20 and the adhesive layer 40.

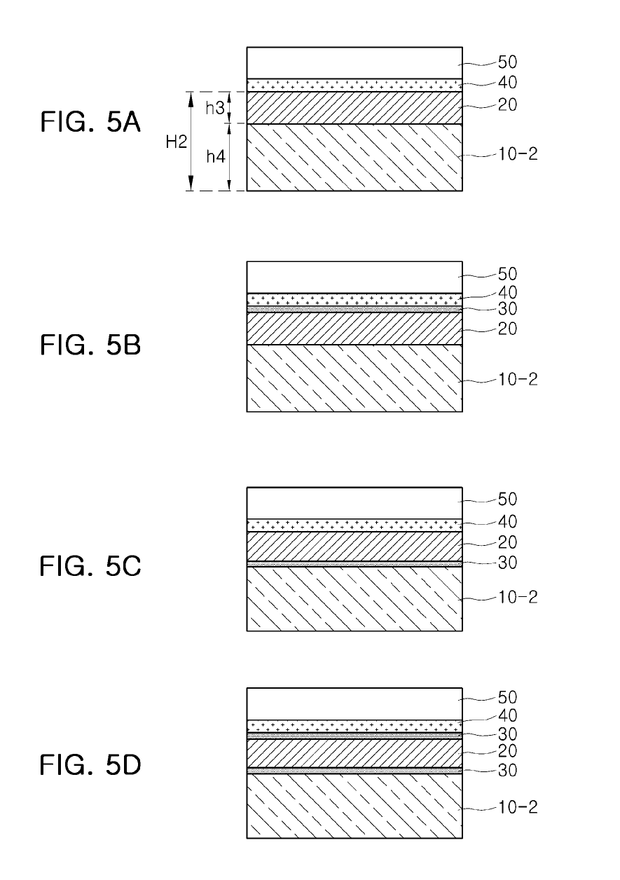

FIGS. 5A through 5D are cross-sectional views of an adhesive tape according to another embodiment of the present invention.

FIGS. 5A through 5D are views showing the adhesive tape in the case in which a reinforcement layer is formed to have a polymer structure.

As shown in FIG. 5A, the adhesive tape may include a polymer reinforcement layer 10-2, a buffer layer 20 formed on one surface of the polymer reinforcement layer 10-2 and performing a buffering operation, an adhesive layer 40 formed on one surface of the buffer layer 20, and a release film 50 formed on one surface of the adhesive layer 40.

According to this embodiment of the present invention, a thickness of a base substrate (H2) including the polymer reinforcement layer 10-2 and the buffer layer 20 may be 50 μm or more.

In the case in which the thickness of the base substrate is 50 μm or less, reinforcement force may be significantly weakened.

Further, according to the embodiment of the present invention, a ratio (h3:h4) of a thickness (h4) of the polymer reinforcement layer 10-2 to a thickness (h3) of the buffer layer 20 may be 1:1 to 1:4.

In the case in which the thickness (h3) of the buffer layer is thicker than the thickness (h4) of the reinforcement layer, an effect of the reinforcement layer may be significantly decreased.

In the case in which the thickness (h3) of the buffer layer is thinner than (that is, is 25% or less of) the thickness (h4) of the reinforcement layer, an effect of the buffer layer may be significantly decreased.

Referring to FIG. 5B, the adhesive tape may further include an adhering layer 30 disposed on an interface between the buffer layer 20 and the adhesive layer 40.

The adhering layer 30 may improve a degree of adhesion between the buffer layer 20 and the adhesive layer 40 respectively disposed on both surfaces thereof.

The adhering layer 30 may include acryl, silicone, urethane, and the like.

The material for the adhering layer 30 may be appropriately selected according to the materials configuring the buffer layer 20 and the reinforcement layer 10-2. A description thereof will be provided in detail below.

Referring to FIG. 5C, the adhesive tape may further include the adhering layer 30 disposed on an interface between the polymer reinforcement layer 10-2 and the buffer layer 20.

The adhering layer 30 may improve a degree of adhesion between the polymer reinforcement layer 10-2 and the buffer layer 20 respectively disposed on both surfaces thereof.

Referring to FIG. 5D, the adhesive tape may further include the adhering layer 30 respectively disposed on the interface between the buffer layer 20 and the adhesive layer 40 and the interface between the polymer reinforcement layer 10-2 and the buffer layer 20.

The plurality of adhering layers 30 may improve a degree of adhesion between the polymer reinforcement layer 10-2, the buffer layer 20 and the adhesive layer 40.

Table 1 shows whether or not a buffering operation is performed according to a process temperature with respect to materials of respective buffer layers.

TABLE 1

| Process | | | | |
|---|---|---|---|---|
| Temperature | | | | |
| (° C.) | PET | PI | PO | PEN |
| 100° C. or less | ◯ | ◯ | ◯ | ◯ |
| 120° C. or less | ◯ | ◯ | ◯ | ◯ |
| 150° C. or less | X | ◯ | X | ◯ |
| 200° C. or less | X | ◯ | X | X |

Here, ◯ represents the case in which the buffer layer may perform the buffering operation, and X represents the case in which the buffer layer may not perform the buffering operation.

Referring to Table 1, polyethylene terephtalate (PET) may perform the buffering operation only in the case in which the process temperature is 120° C. or less. Therefore, PET may be used as the buffer layer in the case in which the process temperature is 120° C. or less.

Further, referring to Table 1, polyolefine (PO) may perform the buffering operation only in the case in which the process temperature is 120° C. or less. Therefore, PO may be used as the buffer layer in the case in which the process temperature is 120° C. or less.

Further, referring to Table 1, polyethylene naphtalate (PEN) may perform the buffering operation only in the case in which the process temperature is 150° C. or less. Therefore, PEN may be used as the buffer layer in the case in which the process temperature is 150° C. or less.

Table 2 shows whether or not a reinforcement operation is performed according to a process pressure with respect to materials of respective reinforcement layers.

TABLE 2

| Process Pressure | Polymer | Metal Foil |
|---|---|---|
| 15 MPa or less | ◯ | ◯ |
| Excess of 15 MPa | X | ◯ |

Here, ◯ represents the case in which the reinforcement layer may perform the reinforcement operation, and X represents the case in which the reinforcement layer may not perform the reinforcement operation.

Referring to Table 2, in the case in which the process pressure is 15 MPa or less, both of the polymer reinforcement layer and the metal foil reinforcement layer may perform the reinforcement operation.

However, in the case in which the process pressure exceeds 15 MPa, only the metal foil reinforcement layer may perform the reinforcement operation.

Therefore, the metal foil reinforcement layer may be used in the case in which the process pressure exceeds 15 MPa.

Table 3 shows a configuration of a buffer layer, an adhering layer, and a reinforcement layer according to a process temperature and a process pressure.

TABLE 3

| | Process Condition | | Configuration | | |
|---|---|---|---|---|---|
| | Temperature | Pressure | Buffer | Adhesive | Reinforcement |
| No. | (° C.) | (MPa) | Layer | Layer | Layer |
| 1 | 120 | 10 | PET, PI, PO, | Acryl, | PET, PI, PO, |
| | | | PEN | Silicone, | PEN, Cu, Al |
| | | | | Urethane | |
| 2 | 120 | 16 | PET, PI, PO, | Acryl, | Cu, Al |
| | | | PEN | Silicone, | |
| | | | | Urethane | |
| 3 | 150 | 10 | PI, PEN | Silicone | PI, PEN, Cu, |
| | | | | | Al |
| 4 | 150 | 16 | PI, PEN | Silicone | Cu, Al |
| 5 | 180 | 16 | PI | Silicone | Cu, Al |

Referring to sample 1, since the process temperature is 120° C., anyone of PET, PI, PO, and PEN may be used as a material for the buffer layer. Further, since the process pressure is 10 MPa, any one of the polymer and the metal foil may be used as a material for the reinforcement layer.

The adhering layer may be determined based on the buffer layer and the reinforcement layer respectively disposed on both surfaces thereof.

Referring to sample 2, since the process temperature is 120° C., anyone of PET, PI, PO, and PEN may be used as a material for the buffer layer. Further, since the process pressure is 16 MPa, the metal foil may be used as a material for the reinforcement layer.

Referring to sample 3, since the process temperature is 150° C., any one of PI and PEN may be used as a material for the buffer layer. Further, since the process pressure is 10 MPa, any one of the polymer and the metal foil may be used as a material for the reinforcement layer.

Referring to sample 4, since the process temperature is 150° C., any one of PI and PEN may be used as a material for the buffer layer. Further, since the process pressure is 16 MPa, the metal foil may be used as a material for the reinforcement layer.

Referring to sample 5, since the process temperature is 180° C., PI may be used as a material for the buffer layer. Further, since the process pressure is 16 MPa, the metal foil may be used as a material for the reinforcement layer.

Meanwhile, in the case in which PI or PEN is used as the buffer layer, silicone may be used as a material for the adhering layer.

In consideration of the process conditions (the process temperature and the process pressure) as described above, an adhesive tape may be provided to have an appropriate configuration.

In the method for producing the substrate, in the case in which the adhesive tape as described above is provided, the occurrence of the residue in the producing process may be decreased.

In the case in which the occurrence of the residue is decreased, an additional process for removing the residue may be omitted, thereby simplifying the producing process.

In addition, a defect ratio of the substrate product due to the residue may be decreased.

As set forth above, according to embodiments of the present invention, an adhesive tape capable of suppressing residue may be provided.

While the present invention has been shown and described in connection with the embodiments, it will be apparent to those skilled in the art that modifications and variations can be made without departing from the spirit and scope of the invention as defined by the appended claims.

What is claimed is:

1. An adhesive tape comprising:
a reinforcement layer supporting the adhesive tape;
a buffer layer formed on one surface of the reinforcement layer and performing a buffering operation; and
an adhesive layer formed on one surface of the buffer layer.

2. The adhesive tape of claim 1, further comprising a release film formed on one surface of the adhesive layer.

3. The adhesive tape of claim 1, further comprising an adhering layer formed on at least one of an interface between the buffer layer and the adhesive layer and an interface between the buffer layer and the reinforcement layer.

4. The adhesive tape of claim 1, wherein the reinforcement layer includes at least one of a copper foil and an aluminum foil.

5. The adhesive tape of claim 1, wherein the reinforcement layer includes at least one of polyethylene terephtalate, polyimde, polyolefine, and polyethylene naphtalate.

6. The adhesive tape of claim 1, wherein the buffer layer includes at least one of polyethylene terephtalate, polyimde, polyolefine, and polyethylene naphtalate.

7. The adhesive tape of claim 1, wherein the adhesive layer includes at least one of acryl, silicone, and urethane.

8. The adhesive tape of claim 2, wherein the release film includes polyethylene terephtalate.

9. The adhesive tape of claim 1, wherein a thickness ratio of the buffer layer to the reinforcement layer is 1:1 to 1:4.

10. A method for producing a substrate, the method comprising
preparing a core substrate having circuit patterns formed on both surfaces thereof and a cavity formed to penetrate through upper and lower portions thereof;
laminating an adhesive tape on a lower surface of the core substrate so as to shield a lower portion of the cavity, the adhesive layer including a reinforcement layer, a buffer layer, and an adhesive layer;
embedding an electronic component in the cavity;
laminating a first insulator on an upper surface of the core substrate;
removing the adhesive tape; and
laminating a second insulator on the lower surface of the core substrate.

11. The method of claim 10, further comprising forming an adhering layer on at least one of an interface between the buffer layer and the adhesive layer and an interface between the buffer layer and the reinforcement layer.
